(19) United States
(12) Patent Application Publication
(10) Pub. No.: US 2025/0298310 A1
(43) Pub. Date: Sep. 25, 2025

(54) SEMICONDUCTOR PHOTORESIST COMPOSITIONS AND METHODS OF FORMING PATTERNS USING THE COMPOSITION

(71) Applicant: SAMSUNG SDI CO., LTD., Yongin-si (KR)

(72) Inventors: Seungyong CHAE, Suwon-si (KR); Sumin JANG, Suwon-si (KR); Bukeun OH, Suwon-si (KR); Sangkyun IM, Suwon-si (KR)

(21) Appl. No.: 19/025,146

(22) Filed: Jan. 16, 2025

(30) Foreign Application Priority Data
Mar. 19, 2024 (KR) 10-2024-0037805

(51) Int. Cl. G03F 7/004

(52) U.S. Cl. CPC G03F 7/0042; G03F 7/0045

(57) ABSTRACT

A semiconductor photoresist composition including an organometallic compound having two radiation-sensitive functional groups and three hydrolyzable ligands and including a pentavalent metal; and a solvent is disclosed. A method of forming or providing patterns using the semiconductor photoresist composition is also disclosed.

### CROSS-REFERENCE TO RELATED APPLICATION

The present application claims priority to and the benefit of Korean Patent Application No. 10-2024-0037805, filed on Mar. 19, 2024, in the Korean Intellectual Property Office, the entire disclosure of which is incorporated herein by reference.

### BACKGROUND

### 1. Field

One or more embodiments of the present disclosure relate to a semiconductor photoresist composition and a method of forming or providing patterns using the semiconductor photoresist composition.

### 2. Description of the Related Art

Extreme ultraviolet (EUV) lithography has drawn attention as one essential technology for manufacturing a next generation semiconductor device (e.g., a semiconductor chip). The EUV lithography is a pattern-forming technology using an EUV ray that has a wavelength of 13.5 nm as an exposure light source. According to the EUV lithography, a fine pattern (e.g., less than or equal to 20 nm) may be formed in an exposure process during a manufacture of a semiconductor device (e.g., a semiconductor chip).

The extreme ultraviolet (EUV) lithography is realized through development of compatible photoresists which may be performed at a spatial resolution of less than or equal to 16 nm. Efforts to satisfy insufficient specifications of chemically amplified (CA) photoresists, such as a resolution, a photospeed, and feature roughness (or also referred to as a line edge roughness or LER), for the next generation device have been or are being made.

An intrinsic image blurring due to an acid catalyzed reaction in the polymer-type or kind photoresists limits a resolution in small feature sizes which has existed in electron beam (e-beam) lithography. The chemically amplified (CA) photoresists are designed for high sensitivity. However, because their elemental makeups reduce light absorbance of the photoresists at a wavelength of 13.5 nm, it may decrease their sensitivity, and the chemically amplified (CA) photoresists may have more difficulties under an EUV exposure.

The CA photoresists may have difficulties with respect to the small feature sizes due to roughness issues, and line edge roughness (LER) of the CA photoresists experimentally may be increased, as a photospeed may be decreased partially due to an essence of acid catalyst processes. A novel high-performance photoresist is desired or required in a semiconductor industry because of these undesirable defects and problems of the CA photoresists.

In order to overcome the aforementioned drawbacks of the chemically amplified (CA) organic photosensitive composition, an inorganic photosensitive composition has been researched. The inorganic photosensitive composition has been mainly or predominantly used for negative tone patterning which has resistance against removal by a developer composition due to chemical modification through nonchemical amplification mechanism. The inorganic composition includes an inorganic element that has a higher EUV absorption rate than hydrocarbon, and thus, it may secure sensitivity through the nonchemical amplification mechanism and may be less sensitive with respect to a stochastic effect and thus may have low line edge roughness and relatively smaller number of undesirable defects.

Inorganic photoresists based on peroxopolyacids of tungsten mixed with tungsten, niobium, titanium, and/or tantalum have been reported as radiation sensitive materials for patterning.

These materials are effective for patterning large pitches for bilayer configuration as far ultraviolet (deep UV), X-ray, and electron beam sources. When cationic hafnium metal oxide sulfate (HfSOx) materials along with a peroxo complexing agent were used to image a 15 nm half-pitch (HP) through projection EUV exposure, improved performance was obtained. This system exhibits a high performance of a non-CA photoresist and has a practicable photospeed near to a requirement for an EUV photoresist. However, the hafnium metal oxide sulfate material including the peroxo complexing agent has some practical drawbacks. First, these materials are coated in a mixture of corrosive sulfuric acid/hydrogen peroxide and have insufficient shelf-life stability. Second, a structural change of the materials for performance improvement as a composite mixture is challenging. Third, development should be performed in a tetramethylammonium hydroxide (TMAH) solution at a high concentration of 25 wt % and/or the like.

To address these issues, research has been focused on developing molecules that include tin (Sn), which have excellent or suitable absorption of extreme ultraviolet rays. As for an organotin polymer among the molecules containing tin, alkyl ligands are dissociated by light absorption or secondary electrons produced. The dissociated alkyl ligands are then crosslinked with adjacent chains through oxo bonds and thus enable the negative tone patterning which may not be removed by an organic developer. Although this organotin polymer exhibits greatly improved sensitivity and maintains a suitable resolution and line edge roughness, the patterning characteristics need to be further improved for commercial availability.

### SUMMARY

One or more aspects of embodiments of the present disclosure are directed toward a semiconductor photoresist composition that may minimize or reduce undesirable patterning defects and process delay effects.

One or more aspects of embodiments of the present disclosure are directed toward a method of forming or providing patterns by using the semiconductor photoresist composition.

One or more aspects of embodiments of the present disclosure are directed toward a photoresist film manufactured by the method of forming or providing patterns.

Additional aspects will be set forth in part in the description which follows and, in part, will be apparent from the description, or may be learned by practice of the presented embodiments of the disclosure.

A semiconductor photoresist composition according to one or more embodiments may include an organometallic compound having two radiation-sensitive functional groups and three hydrolyzable ligands and including a pentavalent metal and a solvent.

A method of forming or providing patterns according to one or more embodiments may include providing an etching-objective layer on a substrate, coating the semiconductor photoresist composition on the etching-objective layer to provide a photoresist layer, exposing and developing the photoresist layer to provide a photoresist film having a photoresist pattern, and etching the etching-objective layer utilizing the photoresist pattern as an etching mask.

A photoresist film according to one or more embodiments may be manufactured by the method of forming or providing patterns as described in one or more embodiments of the present disclosure.

The semiconductor photoresist composition according to one or more embodiments may significantly reduce reactivity with moisture (e.g., chemical reactivity between the semiconductor photoresist composition and moisture) after exposure, thereby mitigating or reducing deviations due to process delays.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIGS. 1A-1E each is a cross-sectional view illustrating a method of forming or providing patterns using a semiconductor photoresist composition according to one or more embodiments.

### DETAILED DESCRIPTION

Hereinafter, referring to the drawings, one or more embodiments of the present disclosure are described in more detail. In the following description of the present disclosure, the functions or constructions that should be generally understood by a person of ordinary skill in the art may not be described in order to clarify the present disclosure.

In order to clearly illustrate embodiments of the present disclosure, certain description and relationships may be omitted, and throughout the present disclosure, substantially the same (or substantially the same) or similar configuration elements or arrangement elements may be designated by substantially the same reference numerals. Also, because the size and thickness of each configuration or arrangement shown in the drawing may be arbitrarily shown for better understanding and ease of description, embodiments of the present disclosure are not necessarily limited thereto.

As utilized herein, the terms “and/or” and “or” may include any and all combinations of one or more of the associated listed items. Expressions, such as “at least one of,” when preceding a list of elements, modify the entire list of elements and do not modify the individual elements of the list.

It will be further understood that the terms “comprise”, “include,” or “have/has,” when utilized in the present disclosure, specify the presence of stated features, integers, steps, operations, elements, and/or components, but do not preclude the presence or addition of one or more other features, integers, steps, operations, elements, components, and/or groups thereof. The “/” utilized below may be interpreted as “and” or as “or” depending on the situation.

As utilized herein, the singular forms “a,” “an,” and “the” are intended to include the plural forms as well, unless the context clearly indicates otherwise. Further, the utilization of “may” when describing embodiments of the present disclosure refers to “one or more embodiments of the present disclosure”.

In the context of the present disclosure and unless otherwise defined, the terms “use,” “using,” and “used” may be considered synonymous with the terms “utilize,” “utilizing,” and “utilized,” respectively.

As utilized herein, the term “about,” or similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may refer to within one or more standard deviations, or within +30%, 20%, 10%, or 5% of the stated value.

Any numerical range recited herein is intended to include all sub-ranges of substantially the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

In the drawings, the thickness of layers, films, panels, regions, and/or the like, may be enlarged for clarity. In the drawings, the thickness of a part of layers or regions, and/or the like, may be exaggerated for clarity. It will be understood that if (e.g., when) an element, such as a layer, film, region, or substrate, is referred to as being “on” another element, it may be directly on the other element or intervening elements may also be present. If (e.g., when) an element is referred to as being “directly on” another element, there may be no intervening elements present.

As used herein, “substituted” refers to replacement of a hydrogen atom by deuterium, a halogen, a carboxyl group, a hydroxy group, a thiol group, a cyano group, a nitro group, —NRR′ (wherein, R and R′ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, or a combination thereof. “Unsubstituted” refers to non-replacement of a hydrogen atom by another substituent and remaining of the hydrogen atom.

As used herein, if (e.g., when) a definition is not otherwise provided, “alkyl group” refers to a linear or branched aliphatic hydrocarbon group. The alkyl group may be “saturated alkyl group” without including any double bond or triple bond.

The alkyl group may be a C1 to C8 alkyl group. For example, the alkyl group may be a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, if (e.g., when) a definition is not otherwise provided, “cycloalkyl group” refers to a monovalent cyclic aliphatic hydrocarbon group.

The cycloalkyl group may be a C3 to C8 cycloalkyl group, for example, a C3 to C7 cycloalkyl group, a C3 to C6 cycloalkyl group, a C3 to C5 cycloalkyl group, or a C3 to C4 cycloalkyl group. For example, the cycloalkyl group may be a cyclopropyl group, a cyclobutyl group, a cyclopentyl group, or a cyclohexyl group, but embodiments of the present disclosure are not limited thereto.

As used herein, “aliphatic unsaturated organic group” refers to a hydrocarbon group including a bond in which the bond between the carbon and carbon atom in the molecule is a double bond, a triple bond, or a combination thereof.

The aliphatic unsaturated organic group may be a C2 to C8 aliphatic unsaturated organic group. For example, the aliphatic unsaturated organic group may be a C2 to C7 aliphatic unsaturated organic group, a C2 to C6 aliphatic unsaturated organic group, a C2 to C5 aliphatic unsaturated organic group, or a C2 to C4 aliphatic unsaturated organic group. For example, the C2 to C4 aliphatic unsaturated organic group may be a vinyl group, an ethynyl group, an allyl group, a 1-propenyl group, a 1-methyl-1-propenyl group, a 2-propenyl group, a 2-methyl-2-propenyl group, a 1-propynyl group, a 1-methyl-1 propynyl group, a 2-propynyl group, a 2-methyl-2-propynyl group, a 1-butenyl group, a 2-butenyl group, a 3-butenyl group, a 1-butynyl group, a 2-butynyl group, or a 3-butynyl group.

As used herein, “aryl group” refers to a substituent in which all atoms in the cyclic substituent have a p-orbital and these p-orbitals are conjugated and may include a monocyclic or fused ring polycyclic functional group (e.g., rings sharing adjacent pairs of carbon atoms).

As used herein, “heteroaryl group” may refer to an aryl group including at least one heteroatom selected from among nitrogen (N), oxygen (O), sulfur (S), phosphorus (P), and silicon (Si). Two or more heteroaryl groups are linked by a sigma bond directly, or if (e.g., when) the heteroaryl group includes two or more rings, the two or more rings may be fused. If (e.g., when) the heteroaryl group is a fused ring, each ring may include one to three heteroatoms.

As used herein, unless otherwise defined, “alkenyl group” refers to an aliphatic unsaturated alkenyl group including at least one double bond as a linear or branched aliphatic hydrocarbon group.

As used herein, unless otherwise defined, “alkynyl group” refers to an aliphatic unsaturated alkynyl group including at least one triple bond as a linear or branched aliphatic hydrocarbon group.

Hereinafter, a semiconductor photoresist composition according to one or more embodiments is disclosed.

The semiconductor photoresist composition according to one or more embodiments may include an organometallic compound having two radiation-sensitive functional groups and three hydrolyzable ligands and including a pentavalent metal, and a solvent.

The organometallic compound according to one or more embodiments of the present disclosure may have two radiation-sensitive functional groups per metal atom and three hydrolyzable ligands, and thus it may form a structurally spherical (e.g., generally spherical) stable cluster, and may have a shielding effect due to the radiation-sensitive functional group. As a result, reactivity with moisture (e.g., chemical reactivity between the semiconductor photoresist composition and moisture) after exposure may be significantly lowered or reduced, thereby mitigating or reducing deviations due to process delays.

The pentavalent metal may be selected from among arsenic (As), antimony (Sb), and bismuth (Bi).

In one or more embodiments, the pentavalent metal may be Sb.

The hydrolyzable ligand may be selected from among an alkoxy or aryloxy group (—OR^{a}, wherein R^{a} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{b}, wherein R^{b} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{c}R^{d}, wherein R^{c} and R^{d} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{e}(COR^{f}), wherein R^{e} and R^{f} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{g}C(NR^{h})Rⁱ, wherein R^{g}, R^{h}, and Rⁱ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthio group (—SR^{j}, wherein R^{j} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a thiocarboxyl group (—S(CO)R^{k}, wherein R^{k} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

As an example, the organometallic compound may be represented by Chemical Formula 1.

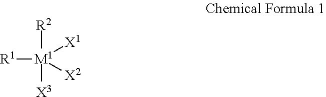

In Chemical Formula 1,
M¹ may be selected from among As, Sb, and Bi,
R¹ and R² may each independently be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group, and
X¹ to X³ may each independently be selected from among an alkoxy or aryloxy group (—OR^{a}, wherein R^{a} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{b}, wherein R^{b} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{c}R^{d}, wherein R^{c} and R^{d} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{e}(COR^{f}), wherein R^{e} and R^{f} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{g}C(NR^{h}) Rⁱ, wherein R^{g}, R^{h}, and Rⁱ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthio group (—SR^{j}, wherein R^{j} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a thiocarboxyl group (—S(CO)R^{k}, wherein R^{k} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

As an example, X¹ to X³ may each independently be selected from among an alkoxy or aryloxy group (—OR^{a}, wherein R^{a} may be a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof), a carboxyl group (—O(CO)R^{b}, wherein R^{b} may be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof), an alkylamido or dialkylamido group (—NR^{c}R^{d}, wherein R^{c} and R^{d} may each independently be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C30 aryl group, or a combination thereof), an amidato group (—NR^{e}(COR^{f}), wherein R^{e} and R^{f} may each independently be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof), an amidinato group (—NR^{g}C(NR^{h}) Rⁱ, wherein R^{g}, R^{h}, and Rⁱ may each independently be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof), an alkylthio or arylthio group (—SR^{j}, wherein R^{j} may be a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof), and a thiocarboxyl group (—S(CO)R^{k}, wherein R^{k} may be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof).

For example, X¹ to X³ may each independently be selected from among an alkoxy or aryloxy group (—OR^{a}, wherein R^{a} may be a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof), a carboxyl group (—O(CO)R^{b}, wherein R^{b} may be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof), and an amidato group (—NR^{e}(COR^{f}), wherein R^{e} and R^{f} may each independently be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof).

For example, R¹ and R² may each independently be a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted tert-pentyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted benzyl group, a substituted or unsubstituted methoxy group, a substituted or unsubstituted ethoxy group, a substituted or unsubstituted propoxy group, or a combination thereof,
R^{a} may be a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted tert-pentyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, or a combination thereof, and
R^{b}, R^{c}, R^{d}, R^{e}, R^{f}, R^{g}, R^{h}, Rⁱ, R^{j}, and R^{k} may each independently be hydrogen, a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted tert-pentyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, or a combination thereof.

In one or more embodiments, the semiconductor photoresist composition may further include at least one selected from among the organometallic compound represented by Chemical Formula 2 and the organometallic compound represented by Chemical Formula 3.

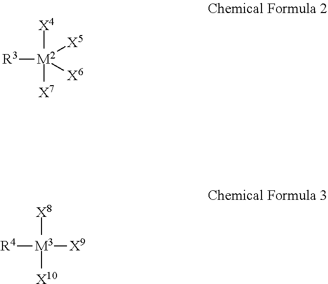

In Chemical Formula 2 and Chemical Formula 3,
M² may be selected from among As, Sb, and Bi,
M³ may be selected from among tin (Sn), lead (Pb), and titanium (Ti),
R³ and R⁴ may each independently be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group, and
X⁴ to X¹⁰ may each independently be selected from among an alkoxy or aryloxy group (—OR^{a}, wherein R^{a} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{b}, wherein R^{b} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{c}R^{d}, wherein R^{c} and R^{d} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{e}(COR^{f}), wherein R^{e} and R^{f} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{g}C(NR^{h}) Rⁱ, wherein R^{g}, R^{h}, and Rⁱ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthio group (—SR^{j}, wherein R^{j} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a thiocarboxyl group (—S(CO)R^{k}, wherein R^{k} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

For example, the organometallic compound represented by Chemical Formula 1: at least one selected from among the organometallic compound represented by Chemical Formula 2 and the organometallic compound represented by Chemical Formula 3 may be in a weight ratio of about 11:1 to about 1:11.

1 For example, the organometallic compound represented by Chemical Formula 1: at least one selected from among the organometallic compound represented by Chemical Formula 2 and the organometallic compound represented by Chemical Formula 3 may be in a weight ratio of about 5:1 to about 1:5, or about 2:1 to about 1:2.

For example, M² may be Sb.

For example, M³ may be Sn.

The organometallic compound represented by Chemical Formula 1 may strongly absorb extreme ultraviolet light at 13.5 nm and may have excellent or suitable sensitivity to high-energy light.

In the semiconductor photoresist composition according to one or more embodiments, based on 100 wt % of the semiconductor photoresist composition, the organometallic compound represented by Chemical Formula 1 may be in an amount of about 0.5 wt % to about 30 wt %, for example, about 1 wt % to about 30 wt %, about 1 wt % to about 25 wt %, for example, about 1 wt % to about 20 wt %, for example, about 1 wt % to about 15 wt %, for example, about 1 wt % to about 10 wt %, for example, about 1 wt % to about 5 wt %, but embodiments of the present disclosure are not limited thereto. If (e.g., when) the organometallic compound represented by Chemical Formula 1 is in the amount within the above range, the storage stability and etch resistance of the semiconductor photoresist composition may be improved or enhanced (e.g., to be a suitable storage stability and etch resistance of the semiconductor photoresist composition), and the resolution characteristics may be improved or enhanced (e.g., to be a suitable resolution characteristics).

Because the semiconductor photoresist composition according to one or more embodiments of the present disclosure may include the organometallic compound according to one or more embodiments, the semiconductor photoresist composition having excellent or suitable sensitivity and pattern formation properties may be provided.

1 The solvent in the semiconductor photoresist composition according to one or more embodiments may be an organic solvent, and may be, for example, aromatic compounds (e.g., xylene, toluene, and/or the like), alcohols (e.g., 4-methyl-2-pentenol, 4-methyl-2-propanol, 1-butanol, methanol, isopropyl alcohol, 1-propanol, and/or the like), ethers (e.g., anisole, tetrahydrofuran, and/or the like), esters (n-butyl acetate, propylene glycol monomethyl ether acetate, ethyl acetate, ethyl lactate, and/or the like), ketones (e.g., methyl ethyl ketone, 2-heptanone, and/or the like), or a mixture thereof, but embodiments of the present disclosure are not limited thereto.

In one or more embodiments, the semiconductor photoresist composition may further include a resin in addition to the organometallic compound and solvent according to one or more embodiments.

The resin may be a phenol-based resin including at least one aromatic moiety selected from among moieties listed in Group 2.

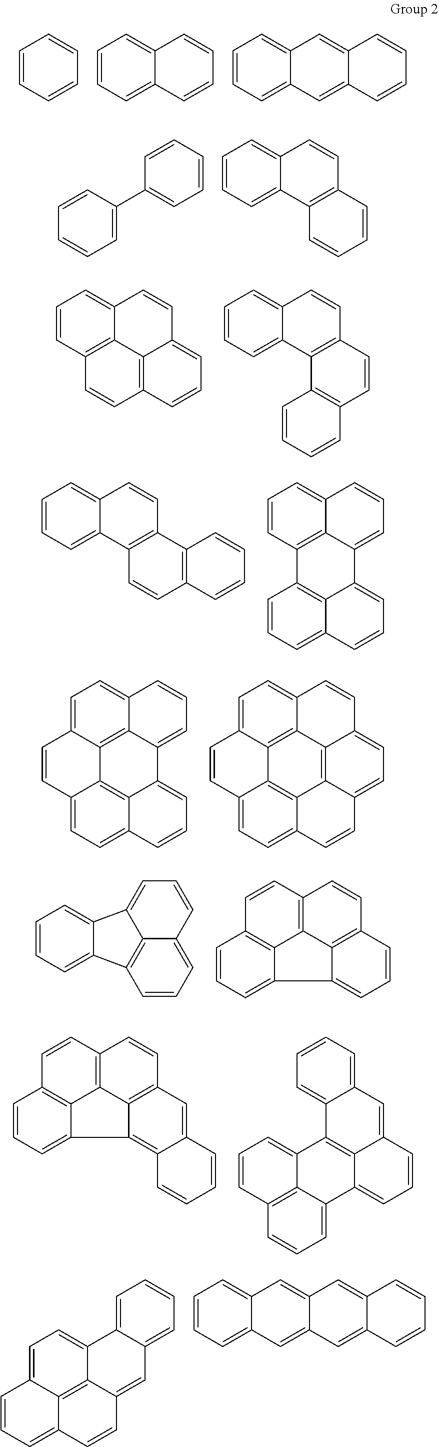

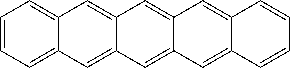 [SMILES: c1ccc2cc3cc4cc5ccccc5cc4cc3cc2c1]

The resin may have a weight average molecular weight of about 500 g/mol to about 20,000 g/mol.

The resin may be in an amount of about 0.1 wt % to about 50 wt % based on a total amount of the semiconductor photoresist composition (e.g., based on 100 wt % of a total amount of the semiconductor photoresist composition).

If (e.g., when) the resin is within the above content (e.g., amount) range, it may have excellent or suitable etching resistance and heat resistance.

In one or more embodiments, the semiconductor photoresist composition according to one or more embodiments may include the organometallic compound, solvent, and resin as described in one or more embodiments of the present disclosure. However, the semiconductor photoresist composition according to one or more embodiments may further include additives in one or more embodiments.

For example, it may further include at least one additional additive selected from among an alcohol-based compound, a thiol-based compound, a carboxylic acid compound, and a phosphoric acid compound.

For example, examples of the additional additive may include ethanethiol, succinic acid, ethane phosphate, and/or the like, but embodiments of the present disclosure are not limited thereto.

The additional additive may be in an amount of about 0.01 to about 1 wt % based on a total amount of the semiconductor photoresist composition (e.g., based on 100 wt % of a total amount of the semiconductor photoresist composition).

For example, the additional additive may be in an amount of about 0.01 to about 1 wt %, or about 0.01 to about 0.5 wt %, based on a total amount of the semiconductor photoresist composition (e.g., based on 100 wt % of a total amount of the semiconductor photoresist composition).

In one or more embodiments, other additives, such as a surfactant, a crosslinking agent, a leveling agent, an organic acid, a quencher, or a combination thereof, may be further included. The semiconductor photoresist composition may further include other additives selected from among a surfactant, a crosslinking agent, a leveling agent, organic acid, a quencher, or a combination thereof.

The surfactant may include, for example, an alkyl benzene sulfonate salt, an alkyl pyridinium salt, polyethylene glycol, a quaternary ammonium salt, or a combination thereof, but embodiments of the present disclosure are not limited thereto.

The crosslinking agent may be, for example, a melamine-based crosslinking agent, a substituted urea-based crosslinking agent, an acryl-based crosslinking agent, an epoxy-based crosslinking agent, or a polymer-based crosslinking agent, but embodiments of the present disclosure are not limited thereto. It may be a crosslinking agent having at least two crosslinking forming substituents, for example, a compound, such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, methoxymethylated thiourea, and/or the like.

The leveling agent may be used to improve or enhance coating flatness (e.g., to be suitable coating flatness) during printing and may be a commercially available or generally available leveling agent.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, or a combination thereof, but embodiments of the present disclosure are not limited thereto.

The quencher may be diphenyl (p-tolyl) amine, methyl diphenyl amine, triphenyl amine, phenylenediamine, naphthylamine, diaminonaphthalene, or a combination thereof.

A use amount of these other additives according to one or more embodiments may be controlled depending on desired or suitable properties.

In one or more embodiments, the semiconductor photoresist composition may further include a silane coupling agent as an adherence enhancer in order to improve or enhance a close-contacting force with the substrate (e.g., in order to improve or enhance adherence of the semiconductor photoresist composition to the substrate). The silane coupling agent may be, for example, a silane compound including a carbon-carbon unsaturated bond, such as vinyltrimethoxysilane, vinyl triethoxysilane, vinyl trichlorosilane, vinyl tris(ß-methoxyethoxy) silane, and/or the like; or 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane; trimethoxy [3-(phenylamino)propyl]silane, and/or the like, but embodiments of the present disclosure are not limited thereto.

The semiconductor photoresist composition may be formed or provided into a pattern having a high aspect ratio without a collapse. In one or more embodiments, in order to form or provide a fine pattern having a width (e.g., line width) of, for example, about 5 nm to about 100 nm, for example, about 5 nm to about 80 nm, for example, about 5 nm to about 70 nm, for example, about 5 nm to about 50 nm, for example, about 5 nm to about 40 nm, for example, about 5 nm to about 30 nm, for example, about 5 nm to about 20 nm, or, for example, about 5 nm to about 10 nm, the semiconductor photoresist composition may be used for a photoresist process using light in a wavelength ranging from about 5 nm to about 150 nm, for example, about 5 nm to about 100 nm, about 5 nm to about 80 nm, about 5 nm to about 50 nm, about 5 nm to about 30 nm, or about 5 nm to about 20 nm. In one or more embodiments, the semiconductor photoresist composition according to one or more embodiments may be used to realize extreme ultraviolet lithography using an EUV light source of a wavelength of about 13.5 nm.

According to according to one or more embodiments, a method of forming or providing patterns using the semiconductor photoresist composition as described in one or more embodiments of the present disclosure may be provided. For example, the manufactured pattern may be a photoresist pattern.

The method of forming or providing patterns according to one or more embodiments may include providing an etching-objective layer on a substrate, coating the semiconductor photoresist composition on the etching-objective layer to provide a photoresist layer, exposing and developing the photoresist layer to provide a photoresist film having a photoresist pattern, and etching the etching-objective layer utilizing the photoresist pattern as an etching mask.

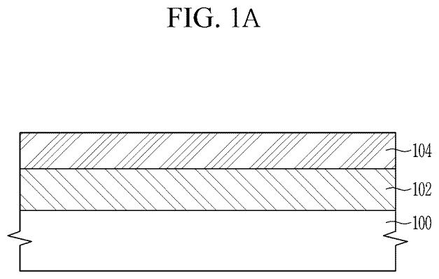

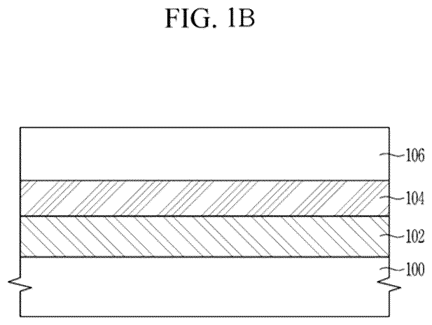

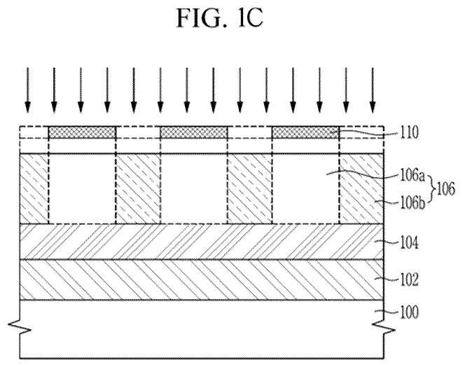

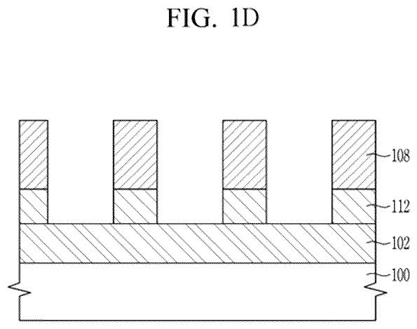

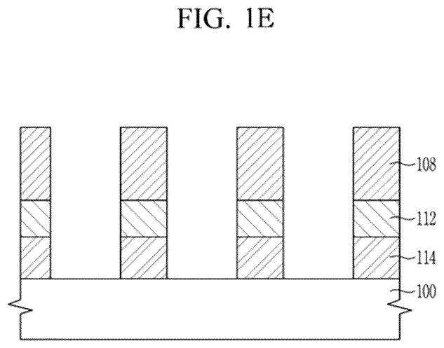

Hereinafter, a method of forming or providing patterns using the semiconductor photoresist composition may be described referring to FIGS. 1A-1E. FIGS. 1A-1E each is a cross-sectional view for illustrating a method of forming or providing patterns using a semiconductor photoresist composition according to one or more embodiments.

Referring to FIG. 1A, an object for etching (e.g., etching-objective layer or etching-target layer) may be prepared. The object for etching may be a thin film 102 on a semiconductor substrate 100. Hereinafter, the object for etching may be limited to the thin film 102. A surface of the thin film 102 may be washed to remove undesirable impurities (e.g., undesirable residues) and/or the like remaining thereon. The thin film 102 may be, for example, a silicon nitride layer, a polysilicon layer, and/or a silicon oxide layer.

Subsequently, the resist underlayer composition that forms or provides a resist underlayer 104 may be spin-coated on the surface of the washed thin film 102. However, one or more embodiments of the present disclosure are not limited thereto, and one or more suitable coating methods, for example, a spray coating, a dip coating, a knife edge coating, a printing method, for example, an inkjet printing and a screen printing, and/or the like may be used.

The coating process of the resist underlayer may not be provided, and hereinafter, a process including a coating of the resist underlayer is described.

Then, the coated composition may be dried and baked to form or provide a resist underlayer 104 on the thin film 102. The baking may be performed at about 100° C. to about 500° C., for example, about 100° C. to about 300° C.

The resist underlayer 104 may be formed or provided between the substrate 100 and a photoresist layer 106 and thus may prevent or reduce non-uniformity (e.g., substantial non-uniformity) and improve pattern formability of a photoresist line width if (e.g., when) a ray reflected from on the interface between the substrate 100 and the photoresist layer 106 or a hardmask between layers is scattered into an unintended photoresist region.

Referring to FIG. 1B, the photoresist layer 106 may be formed or provided by coating the semiconductor photoresist composition on the resist underlayer 104. The photoresist layer 106 may be obtained by coating the semiconductor photoresist composition according to one or more embodiments on the thin film 102 that may be formed or provided on the substrate 100 and then, curing it through a heat treatment.

For example, the formation of a pattern by using the semiconductor photoresist composition may include coating the semiconductor photoresist composition on the substrate 100 having the thin film 102 through spin coating, slit coating, inkjet printing, and/or the like and then, drying it to form or provide the photoresist layer 106.

The photoresist layer may partially include at least one selected from among moieties represented by Chemical Formula 4-1 to Chemical Formula 4-5.

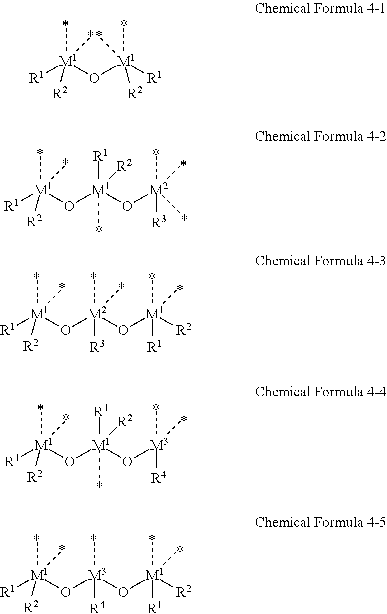

In Chemical Formula 4-1 to Chemical Formula 4-5,
M¹ and M² may each independently be selected from among As, Sb, and Bi,
M³ may be selected from among Sn, Pb, and Ti, and
R¹ to R⁴ may each independently be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group.

The semiconductor photoresist composition has already been illustrated in more detail and will not be illustrated again.

Subsequently, a substrate 100 having the photoresist layer 106 may be subjected to a first baking process. The first baking process may be performed at about 80° C. to about 120° C.

Referring to FIG. 1C, the photoresist layer 106 may be selectively exposed using a patterned mask 110.

For example, the exposure may use an activation radiation with light having a high energy wavelength, such as EUV (extreme ultraviolet; a wavelength of about 13.5 nm), an E-Beam (an electron beam), and/or the like, as well as light having a short wavelength, such as an i-line (a wavelength of about 365 nm), a KrF excimer laser (a wavelength of about 248 nm), an ArF excimer laser (a wavelength of about 193 nm), and/or the like.

For example, light for the exposure according to one or more embodiments may have a wavelength ranging from about 5 nm to about 150 nm and/or a high energy wavelength, for example, EUV (extreme ultraviolet; a wavelength of 13.5 nm), an E-Beam (an electron beam), and/or the like.

The exposed region 106b of the photoresist layer 106 may have a different solubility from the unexposed region 106a of the photoresist layer 106 by forming or providing a polymer by a crosslinking reaction, such as condensation reaction(s) between organometallic compounds.

Subsequently, the substrate 100 may be subjected to a second baking process. The second baking process may be performed at a temperature of about 90° C. to about 200° C. The exposed region 106b of the photoresist layer 106 may become easily indissoluble regarding a developer due to the second baking process.

In FIG. 1D, the unexposed region 106a of the photoresist layer may be dissolved and removed using the developer to form or provide a photoresist pattern 108. For example, the unexposed region 106a of the photoresist layer may be dissolved and removed by using an organic solvent, such as 2-heptanone and/or the like, to complete the photoresist pattern 108 corresponding to the negative tone image.

According to one or more embodiments, a developer used in a method of forming or providing patterns according to one or more embodiments may be an organic solvent. The organic solvent used in the method of forming or providing patterns according to one or more embodiments may be, for example, ketones, such as methylethylketone, acetone, cyclohexanone, 2-heptanone, and/or the like, alcohols, such as 4-methyl-2-propanol, 1-butanol, isopropanol, 1-propanol, methanol, and/or the like, esters, such as propylene glycol monomethyl ether acetate, ethyl acetate, ethyl lactate, n-butyl acetate, butyrolactone, and/or the like, aromatic compounds, such as benzene, xylene, toluene, and/or the like, or a combination thereof.

However, the photoresist pattern according to one or more embodiments may not be necessarily limited to the negative tone image but may be formed or provided to have a positive tone image. Herein, a developer that forms or provides the positive tone image may be a quaternary ammonium hydroxide composition, such as tetraethylammonium hydroxide, tetrapropylammonium hydroxide, tetrabutylammonium hydroxide, or a combination thereof.

According to one or more embodiments, exposure to light having a high energy, such as EUV (extreme ultraviolet; a wavelength of 13.5 nm), an E-Beam (an electron beam), and/or the like, as well as light having a short wavelength, such as i-line (wavelength of about 365 nm), KrF excimer laser (wavelength of about 248 nm), ArF excimer laser (wavelength of about 193 nm), and/or the like, may provide a photoresist pattern 108 having a width of a thickness of about 5 nm to about 100 nm. For example, the photoresist pattern 108 may have a width of a thickness of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, or about 5 nm to about 10 nm.

In one or more embodiments, the photoresist pattern 108 may have a pitch having (with) a half-pitch of less than or equal to about 50 nm, for example, less than or equal to about 40 nm, for example, less than or equal to about 30 nm, for example, less than or equal to about 20 nm, or, for example, less than or equal to about 10 nm, and a line width roughness of less than or equal to about 5 nm, or less than or equal to about 3 nm, less than or equal to about 2 nm, or less than or equal to about 1 nm.

According to one or more embodiments, a photoresist film manufactured by the method of forming or providing patterns as described in one or more embodiments may be provided.

Subsequently, the photoresist pattern 108 on the photoresist film may be used as an etching mask to etch the resist underlayer 104. Through this etching process, an organic layer pattern 112 may be formed. The organic layer pattern 112 also may have a width (e.g., line width) corresponding to that of the photoresist pattern 108.

Referring to FIG. 1E, the exposed thin film 102 may be etched by applying the photoresist pattern 108 as an etching mask. As a result, the thin film may be formed or provided as a thin film pattern 114.

The etching of the thin film 102 may be, for example, dry etching using an etching gas and the etching gas may be, for example, CHF₃, CF₄, Cl₂, BCl₃ and a mixed gas thereof.

In the exposure process, the thin film pattern 114 formed or provided by utilizing the photoresist pattern 108 formed or provided through the exposure process performed by using an EUV light source may have a width (e.g., line width) corresponding to that of the photoresist pattern 108. For example, the thin film pattern 114 may have a width (e.g., line width) of about 5 nm to about 100 nm which may be equal to that of the photoresist pattern 108. For example, the thin film pattern 114 formed or provided by utilizing the photoresist pattern 108 formed or provided through the exposure process performed by using an EUV light source may have a width (e.g., line width) of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, and, for example, a width (e.g., line width) of less than or equal to about 20 nm, like that of the photoresist pattern 108.

Hereinafter, the subject matter of the present disclosure will be described in more detail through examples of the preparation of the semiconductor photoresist composition according to one or more embodiments of the present disclosure. However, the present disclosure is technically not restricted by the following examples.

### Synthesis of Organometallic Compound

### Synthesis Example 1: Synthesis of Compound P-1, Diphenylantimony Trichloride

10.0 g (28.3 mmol) of triphenylantimony and 3.23 g (14.2 mmol) of antimony trichloride were to a 250 mL 1-neck round bottom flask and then, stirred in an oil bath at 70° C. to proceed a reaction at room temperature (25±3° C.) for 2 days. Subsequently, 100 mL of dichloromethane (DCM) was added to the resultant reactant to completely dissolve it, and 42.5 mL (42.5 mmol) of a 1 M sulfuryl chloride DCM solution was slowly added thereto in a dropwise fashion. After stirring the resultant mixture for 24 hours, 80 mL of DCM was added thereto and allowed to stand at −20° C. in a freezer, obtaining 8.3 g of crystals.

### Synthesis Example 2: Synthesis of Compound P-2, Diphenylantimony Tripropionate

2.09 g (5.47 mmol) of the compound according to Synthesis Example 1, diphenylantimony trichloride, was dissolved in 100 mL of toluene, and an excessive amount of propionic acid and 2.02 g (18.0 mmol) of potassium propionate were sequentially added thereto. After purging with nitrogen (e.g., nitrogen gas or N₂), the resultant mixture was stirred under reflux for one day in an oil bath at 110° C.

Subsequently, after removing the solvent and the propionic acid at 80° C. under a low pressure, the resultant residue was dissolved in 50 mL of DCM and then, filtered. The resultant filtered solution was treated under nitrogen to remove DCM, obtaining 2.7 g of a light yellow solid.

### Synthesis Example 3: Synthesis of Compound P-3, Monophenylantimony Tetrachloride

5.0 g (14.2 mmol) of triphenylantimony and 6.46 g (28.4 mmol) of antimony trichloride were added to a 250 mL 1-neck round bottom flask and stirred in an oil bath at 70° C. and then, reacted at room temperature for 2 days. Subsequently, 120 mL of dichloromethane (DCM) was added to the resultant reactant to completely dissolve it, and 42.5 ml (42.5 mmol) of a sulfuryl chloride 1 M DCM solution was slowly added thereto in a dropwise fashion. After stirring the resultant mixture for 24 hours, 100 mL of DCM was added thereto and then, allowed to stand in a freezer at −20° C. for one day, obtaining 6.2 g of crystals.

### Synthesis Example 4: Synthesis of Compound P-4, Monophenylantimony Tetrapropionate

2.00 g (5.87 mmol) of the compound of Synthesis Example 3, monophenylantimony tetrachloride, was dissolved in 100 ml of toluene, and an excessive amount of propionic acid and 2.11 g (18.8 mmol) of potassium propionate were sequentially added thereto. The resultant mixture was purged with nitrogen (e.g., nitrogen gas or N₂) and stirred under reflux for one day in an oil bath at 110° C. Subsequently, after removing the solvent and the propionic acid at 80° C. under a low pressure, the resultant residue was dissolved in 50 mL of DCM and then, filtered. The resultant filtered solution was treated to remove DCM under nitrogen, obtaining 2.1 g of a light yellow solid.

### Synthesis Example 5: Synthesis of Compound P-5, Monophenyltin Tripropionate

3.0 g (7.02 mmol) of tetraphenyltin and 5.49 g (21.1 mmol) of tin tetrachloride were added to a 250 mL 1-neck round bottom flask and then, stirred in an oil bath at 80° C. and reacted for 2 days at room temperature. Subsequently, 20.8 g (281 mmol) of propionic acid was added thereto and then, stirred under reflux for 1 day at 130° C. Then, the solvent and the propionic acid were removed therefrom under a low pressure at 100° C., obtaining 11.3 g of a viscous light yellow liquid.

### Synthesis Example 6: Synthesis of Compound P-6, Dibenzyl Phenyl Antimony

5.0 g (14.2 mmol) of triphenylantimony and 6.46 g (28.4 mmol) of antimony trichloride were added to a 250 mL 1-neck round bottom flask and then, stirred in an oil bath at 70° C. and reacted for 2 days at room temperature. Subsequently, the resultant was dissolved in 40 mL of anhydrous tetrahydrofuran (THF), and 85.2 mL (85.2 mmol) of a 1 M benzyl magnesium chloride THE solution was slowly added thereto in a dropwise fashion at 0° C. Then, the resultant mixture was stirred at room temperature for one day and treated to remove THE under a low pressure, obtaining 15.1 g of a solid.

### Synthesis Example 7: Synthesis of Compound P-7, Dibenzyl Antimony Trichloride

In a 100 mL 1-neck round bottom flask, 5.0 g (12.2 mmol) of the dibenzyl phenyl antimony of Synthesis Example 6 was dissolved in 30 mL of DCM, and 6.1 ml (12.2 mmol) of an HCl 2 M diethyl ether solution was slowly added thereto in a dropwise fashion at −78° C. Subsequently, the resultant mixture was stirred for one day at room temperature, and 12.2 mL (12.2 mmol) of a sulfuryl chloride 1 M DCM solution was slowly added thereto in a dropwise fashion. The mixture was stirred for 24 hours, and 80 mL of DCM was added thereto and then, allowed to stand at −20° C. in a freezer for one day, obtaining 4.3 g of crystals.

### Synthesis Example 8: Synthesis of Compound P-8, Dibenzyl Antimony Tripropionate

A light yellow solid, dibenzyl antimony tripropionate, was obtained in substantially the same manner as in Synthesis Example 2 except that the dibenzyl antimony trichloride of Synthesis Example 7 was used instead of the diphenylantimony trichloride of Synthesis Example 1.

### Synthesis Example 9: Synthesis of Compound P-9, Benzyl Diphenyl Antimony

10.0 g (28.4 mmol) of triphenylantimony and 3.23 g (14.2 mmol) of antimony trichloride were added to a 250 mL 1-neck round bottom flask and then, stirred in an oil bath at 70° C. and then, reacted at room temperature for 2 days. Subsequently, the resultant was dissolved in 40 mL of anhydrous tetrahydrofuran (THF), and 42.6 mL (42.6 mmol) of a benzyl magnesium chloride 1 M THF solution was slowly added thereto in a dropwise fashion at 0° C. Then, the resultant mixture was stirred at room temperature for one day and treated to remove THE under a low pressure, obtaining 12.7 g of a solid.

### Synthesis Example 10: Synthesis of Compound P-10, Monobenzyl Antimony Tetrachloride

4.65 g (12.2 mmol) of the benzyl diphenyl antimony of Synthesis Example 9 was dissolved in 30 mL of DCM in a 100 mL 1-neck round bottom flask, and 6.1 mL (12.2 mmol) of an HCl 2 M diethyl ether solution was slowly added thereto in a dropwise fashion at −78° C. Subsequently, the resultant mixture was stirred at room temperature for one day, and 12.2 mL (12.2 mmol) of a sulfuryl chloride 1 M DCM solution was slowly added thereto in a dropwise fashion. After stirring the mixture for 24 hours, 80 mL of DCM was added thereto and then, allowed to stand for one day in a freezer at −20° C., obtaining 3.1 g of crystals.

### Synthesis Example 11: Synthesis of Compound P-11, Monobenzylantimony Tetrapropionate

A light yellow solid, monobenzyl antimony tetrapropionate, was obtained in substantially the same manner as in Synthesis Example 4 except that the monobenzylantimony tetrachloride of Synthesis Example 10 was used instead of the monophenylantimony tetrachloride of Synthesis Example 3 at a yield of 65%.

### Synthesis Example 12: Synthesis of Compound P-12, Diphenylantimony Tripropoxide

2.09 g (5.47 mmol) of the compound of Synthesis Example 1, diphenylantimony trichloride, was dissolved in 100 mL of anhydrous ether, and 1.35 g (16.4 mmol) of sodium propoxide was slowly added thereto in a dropwise fashion at 0° C. Subsequently, the resultant mixture was stirred at room temperature for one day.

Then, after removing the solvent at 50° C. under a low pressure, the resultant residue was dissolved in 50 mL of DCM and then, filtered. The resultant filtered solution was treated under nitrogen to remove DCM, obtaining 2.3 g of a light yellow solid.

### Preparation of Semiconductor Photoresist Compositions

### Examples 1 to 17 and Comparative Examples 1 to 5

The organometallic compounds obtained in Synthesis Examples 1 to 12 were dissolved in xylene at a concentration of 3 wt % having the composition shown in Table 1, and then filtered through a 0.1 μm polytetrafluoroethylene (PTFE) syringe filter to prepare semiconductor photoresist compositions.

TABLE 1

| | First | Second | | |
|---|---|---|---|---|
| | organo- | organo- | | |
| | metallic | metallic | | |
| | compound | compound | | |
| | (wt %) | (wt %) | Additive | Solvent |
| Example 1 | P-2 (3.0) | — | — | xylene |
| Example 2 | P-2 (2.0) | P-4 (1.0) | — | xylene |
| Example 3 | P-2 (2.0) | P-5 (1.0) | — | xylene |
| Example 4 | P-2 (2.7) | — | Ethane thiol (0.3) | xylene |
| Example 5 | P-2 (2.7) | — | Succinic acid (0.3) | xylene |
| Example 6 | P-2 (2.7) | — | Ethane phosphoric | xylene |
| | | | acid (0.3) | |
| Example 7 | P-2 (1.8) | P-4 (0.9) | Ethane thiol (0.3) | xylene |
| Example 8 | P-2 (1.8) | P-4 (0.9) | Succinic acid (0.3) | xylene |
| Example 9 | P-2 (1.8) | P-4 (0.9) | Ethane phosphoric | xylene |
| | | | acid (0.3) | |
| Example 10 | P-8 (3.0) | — | — | xylene |
| Example 11 | P-8 (2.0) | P-11 (1.0) | — | xylene |
| Example 12 | P-12 (3.0) | — | — | xylene |
| Example 13 | P-12 (2.0) | P-4 (1.0) | — | xylene |
| Example 14 | P-12 (2.0) | P-5 (1.0) | — | xylene |
| Example 15 | P-12 (3.0) | — | Ethane thiol (0.3) | xylene |
| Example 16 | P-12 (3.0) | — | Succinic acid (0.3) | xylene |
| Example 17 | P-12 (3.0) | — | Ethane phosphoric | xylene |
| | | | acid (0.3) | |
| Comparative | P-5 (3.0) | — | — | xylene |
| Example 1 | | | | |
| Comparative | P-5 (2.7) | — | Ethane thiol (0.3) | xylene |
| Example 2 | | | | |
| Comparative | P-5 (2.7) | — | Succinic acid (0.3) | xylene |
| Example 3 | | | | |
| Comparative | P-5 (2.7) | — | Ethane phosphoric | xylene |
| Example 4 | | | acid (0.3) | |
| Comparative | P-4 (3.0) | — | — | xylene |
| Example 5 | | | | |

### Evaluation 1: Evaluation of Sensitivity and Line Edge Roughness (LER)

Each of the photoresist compositions according to Examples and Comparative Examples was spin-coated for 30 seconds at 1500 rpm, respectively, on a 200 mm circular silicon wafer whose surface was deposited with hexamethyldisilizane (HMDS), baked at 110° C. for 60 seconds (After application, it was baked (post-apply bake, PAB), and left at room temperature (23±2° C.) for 30 seconds).

Subsequently, a straight line array of 50 circular pads having a diameter of 500 μm was projected onto a wafer on which the composition for a photoresist was coated by using EUV light (Lawrence Berkeley National Laboratory Micro Exposure Tool, MET). Pad exposure time was adjusted to ensure that the EUV light in an increased dose was applied to each pad.

Then, the resist and the substrate were baked at 160° C. for 120 seconds on a hot plate after the exposure. The baked film was developed with a propylene glycol methyl ether acetate (PGMEA) solvent to form a negative tone image. Finally, the obtained film was baked again at 150° C. for 2 minutes on the hot plate, completing the process.

The residual resist thickness of the exposed pad was measured using an ellipsometer. The remaining thickness was measured for each exposure dose and graphed as a function of the exposure dose to measure Eop (energy of optimum), sensitivity was evaluated according to the following criteria, and the results are shown in Table 2.

In one or more embodiments, the line edge roughness (LER) of the line & space pattern was measured using an electron microscope.

These results were evaluated according to the following criteria and are shown in Table 2.

### Evaluation Criteria of Sensitivity

A: Relative value to Eop of Comparative Example 1 is less than 50%
B: Relative value to Eop of Comparative Example 1 is greater than or equal to 50% and less than 100%
C: Relative value to Eop of Comparative Example 1 is greater than or equal to 100%

### Evaluation Criteria of Line Edge Roughness (LER)

A: less than or equal to 4 nm
B: greater than 4 nm and less than or equal to 7 nm
C: greater than 7 nm

### Evaluation 2: Evaluation of Process Delay Stability

After completing the process, a line/space CD pattern was formed or provided on the pattern wafer, which was then transferred to CD-SEM measurement equipment (GC-9380, Hitachi) to measure the CD (Critical Dimension) size of the area where the half-pitch of the mask pattern is 14 nm, and the minimum value among space CDs, which is the distance between lines, were measured. The CD size change rate calculated according to Equation 1 was measured according to the following criteria, and the results are shown in Table 2. The measurement error is ±1.0 nm.

$$Δ CD \text{:} CD when there is no delay after exposure - CD when there is a 30 - minute delay after exposure \qquad Equation 1$$

### Evaluation Criteria

AA: ΔCD less than 3%
A: ΔCD greater than or equal to 3% and less than 5%
B: ΔCD greater than or equal to 5% and less than 10%
C: ΔCD greater than or equal to 10%

TABLE 2

| | Sensitivity | LER | Process delay stability |
|---|---|---|---|
| Example 1 | B | C | A |
| Example 2 | B | B | AA |
| Example 3 | B | B | A |
| Example 4 | A | B | B |
| Example 5 | B | B | A |
| Example 6 | B | B | B |
| Example 7 | A | B | A |
| Example 8 | A | A | A |
| Example 9 | A | B | A |
| Example 10 | A | B | B |
| Example 11 | A | B | A |
| Example 12 | B | B | A |
| Example 13 | B | B | AA |
| Example 14 | A | A | A |
| Example 15 | A | B | A |
| Example 16 | A | B | A |
| Example 17 | A | B | A |
| Comparative Example 1 | C | B | C |
| Comparative Example 2 | B | C | C |
| Comparative Example 3 | B | B | C |
| Comparative Example 4 | A | C | C |
| Comparative Example 5 | C | — | — |

From the results in Table 2, the patterns formed or provided using the semiconductor photoresist compositions according to Examples 1 to 17 exhibit superior sensitivity and/or LER and stability characteristics against process delays compared to Comparative Examples 1 to 5.

Hereinbefore, certain embodiments of the present disclosure have been described and illustrated, however, it should be apparent to a person having ordinary skill in the art that the present disclosure is not limited to the embodiments as described, and may be suitably modified and transformed without departing from the spirit and scope of the present disclosure. In one or more embodiments, the modified or transformed embodiments as such may not be understood separately from the technical ideas and aspects of one or more embodiments of the present disclosure, and the modified embodiments may be within the scope of the appended claims and equivalents thereof of the present disclosure.

### DESCRIPTION OF SYMBOLS

100: substrate
102: thin film
104: resist underlayer
106: photoresist layer
106a: unexposed region
106b: exposed region
108: photoresist pattern
112: organic layer pattern
110: patterned mask
114: thin film pattern

What is claimed is:

1. A semiconductor photoresist composition, comprising:
an organometallic compound having two radiation-sensitive functional groups and three hydrolyzable ligands and comprising a pentavalent metal; and
a solvent.

2. The semiconductor photoresist composition as claimed in claim 1, wherein the pentavalent metal is one selected from among arsenic (As), antimony (Sb), and bismuth (Bi).

3. The semiconductor photoresist composition as claimed in claim 1, wherein:
the hydrolyzable ligand is one selected from among an alkoxy or aryloxy group (—OR^{a}, wherein R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{b}, wherein R^{b} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{c}R^{d}, wherein R^{c} and R^{d} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{e}(COR^{f}), wherein R^{e} and R^{f} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{g}C(NR^{h}) Rⁱ, wherein R^{g}, R^{h}, and Rⁱ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthio group (—SR^{j}, wherein R^{j} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a thiocarboxyl group (—S(CO)R^{k}, wherein R^{k} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

4. The semiconductor photoresist composition as claimed in claim 1, wherein:
the organometallic compound is represented by Chemical Formula 1: 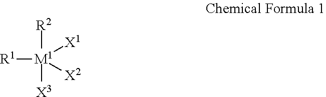
wherein, in Chemical Formula 1,
M¹ is selected from among As, Sb, and Bi,
R¹ and R₂ are each independently selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group, and
X¹ to X³ are each independently selected from among an alkoxy or aryloxy group (—OR^{a}, wherein R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{b}, wherein R^{b} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{c}R^{d}, wherein R^{c} and R^{d} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{e}(COR^{f}), wherein R^{e} and R^{f} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{g}C(NR^{h}) Rⁱ, wherein R^{g}, R^{h}, and Rⁱ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthio group (—SR^{j}, wherein R^{j} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a thiocarboxyl group (—S(CO)R^{k}, wherein R^{k} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

5. The semiconductor photoresist composition as claimed in claim 4, wherein:
X¹ to X³ are each independently selected from among an alkoxy or aryloxy (—OR^{a}, wherein R^{a} is a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof), a carboxyl group (—O(CO)R^{b}, wherein R^{b} is hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof), an alkylamido or dialkylamido group (—NR^{c}R^{d}, wherein R^{c} and R^{d} are each independently hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C30 aryl group, or a combination thereof), an amidato group (—NR^{e}(COR^{f}), wherein R^{e} and R^{f} are each independently hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof), an amidinato group (—NR^{g}C(NR^{h}) Rⁱ, wherein R^{g}, R^{h}, and Rⁱ are each independently hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof), an alkylthio or arylthio group (—SR^{j}, wherein R^{j} is a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof), and a thiocarboxyl group (—S(CO)R^{k}, wherein R^{k} is hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof).

6. The semiconductor photoresist composition as claimed in claim 5, wherein:
the X¹ to X³ are each independently selected from among an alkoxy or aryloxy group (—OR^{a}, wherein R^{a} is a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof), a carboxyl group (—O(CO)R^{b}, wherein R^{b} is hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof), and an amidato group (—NR^{e}(COR^{f}), wherein R^{e} and R^{f} are each independently hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof).

7. The semiconductor photoresist composition as claimed in claim 4, wherein:
R¹ and R₂ are each independently a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted tert-pentyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted benzyl group, a substituted or unsubstituted methoxy group, a substituted or unsubstituted ethoxy group, a substituted or unsubstituted propoxy group, or a combination thereof,
R^{a} is a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted tert-pentyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, or a combination thereof, and
R^{b}, R^{c}, R^{d}, R^{e}, R^{f}, R^{g}, R^{h}, Rⁱ, R^{j}, and R^{k} are each independently hydrogen, a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted tert-pentyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, or a combination thereof.

8. The semiconductor photoresist composition as claimed in claim 1, wherein:
the semiconductor photoresist composition further comprises at least one selected from among the organometallic compound represented by Chemical Formula 2 and the organometallic compound represented by Chemical Formula 3: 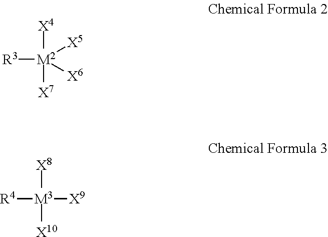
wherein, in Chemical Formula 2 and Chemical Formula 3,
M² is selected from among As, Sb, and Bi,
M³ is selected from among tin (Sn), lead (Pb), and titanium (Ti),
R³ and R⁴ are each independently selected from among a C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group, and
X⁴ to X¹⁰ are each independently selected from among an alkoxy or aryloxy group (—OR^{a}, wherein R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{b}, wherein R^{b} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{c}R^{d}, wherein R^{c} and R^{d} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{e}(COR^{f}), wherein R^{e} and R^{f} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{g}C(NR^{h}) Rⁱ, wherein R^{g}, R^{h}, and Rⁱ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthio group (—SR^{j}, wherein R^{j} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a thiocarboxyl group (—S(CO)R^{k}, wherein R^{k} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

9. The semiconductor photoresist composition as claimed in claim 8, wherein:
the organometallic compound represented by Chemical Formula 1: at least one selected from among the organometallic compound represented by Chemical Formula 2 and the organometallic compound represented by Chemical Formula 3 are in a weight ratio of about 11:1 to about 1:11.

10. The semiconductor photoresist composition as claimed in claim 1, wherein:
the organometallic compound represented by Chemical Formula 1 is in an amount of about 0.5 wt % to about 30 wt % based on 100 wt % of the semiconductor photoresist composition.

11. The semiconductor photoresist composition as claimed in claim 1, wherein:
the semiconductor photoresist composition further comprises at least one additive selected from among an alcohol-based compound, a thiol-based compound, a carboxylic acid compound, and a phosphoric acid compound.

12. The semiconductor photoresist composition as claimed in claim 1, wherein:
the semiconductor photoresist composition further comprises other additives selected from among a surfactant, a crosslinking agent, a leveling agent, organic acid, a quencher, or a combination thereof.

13. A method of forming patterns, comprising:
providing an etching-objective layer on a substrate;
coating the semiconductor photoresist composition as claimed in claim 1 on the etching-objective layer to provide a photoresist layer;
exposing and developing the photoresist layer to provide a photoresist film having a photoresist pattern; and
etching the etching-objective layer utilizing the photoresist pattern as an etching mask.

14. The method as claimed in claim 13, wherein
the photoresist layer comprises at least one selected from among moieties represented by Chemical Formula 4-1 to Chemical Formula 4-5: 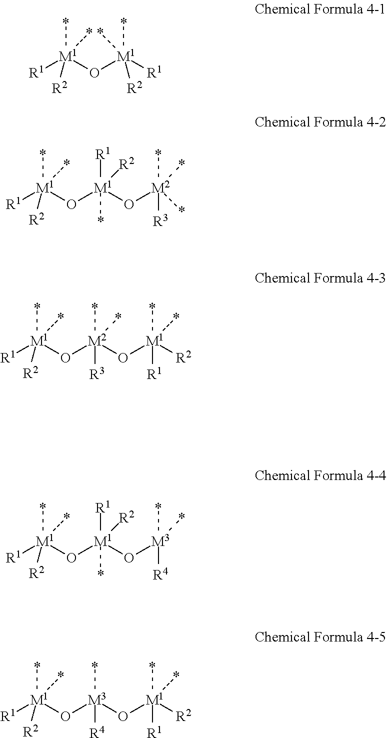
wherein, in Chemical Formula 4-1 to Chemical Formula 4-5,
M¹ and M² are each independently selected from among arsenic (As), antimony (Sb), and bismuth (Bi),
M³ is selected from among tin (Sn), lead (Pb), and titanium (Ti), and
R¹ to R⁴ are each independently selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group.

15. A photoresist film manufactured in the method of forming patterns as claimed in claim 13.
